(19) United States
(12) Patent Application Publication
(10) Pub. No.: US 2007/0034986 A1
(43) Pub. Date: Feb. 15, 2007

(54) Semiconductor device

(75) Inventors: Yoshitaka Hokomoto, Kawasaki-shi (JP); Akio Takano, Kawasaki-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/282,649

(22) Filed: Nov. 21, 2005

(30) Foreign Application Priority Data
Aug. 12, 2005 (JP) 2005-234081

(51) Int. Cl. H01L 29/00

(52) U.S. Cl. 257/500

(57) ABSTRACT

Disclosed is a semiconductor device including a base region having a first conductive type, a drain region and a source region having a second conductive type, a gate insulation film and a gate electrode formed on a channel formation region and on a part of the drain region and the source region, a short electrode formed to include a top of another part of the source region, with contact length being 0.4 μm to 0.8 μm in a part of maximum length with the source region in a direction in which the source region is opposed to the drain region, and a fourth region having the first conductive type and a higher impurity concentration than the base region, provided at an opposite side of the source region from a side opposed to the drain region and at an underside of the short electrode to be adjacent to the base region.

### CROSS-REFERENCE TO THE INVENTION

This application is based upon and claims the benefit of priority from the prior Japanese Patent Application No. 2005-234081, filed on Aug. 12, 2005; the entire contents of which are incorporated herein by reference.

### BACKGROUND

1. Field of the Invention

This invention relates to a semiconductor device for switching an electric current, and particularly to a semiconductor device preferable for an electric power use.

2. Description of the Related Art

When a power field-effect transistor is used for a high-speed switching device or the like, a high surge-voltage is applied between a drain and a source at a gate turn-off timing due to an inductance of the circuit itself, and the surge voltage sometimes exceeds the maximum rating of the device and breaks the device. It is conventionally essential to protect the device by attaching a surge absorbing circuit. However, in terms of the reduction in the number of components and the decrease in size of apparatuses, the demand to remove the serge absorbing circuit and to cause the power field-effect transistor to absorb the energy even when the surge voltage exceeds the maximum rating grows more and more. The performance requirement recently becomes general in the form of an avalanche withstand assurance.

For such assurance, in designs decreasing the impurity concentration in an n-type source layer and increasing the impurity concentration of a p-type base layer and the like, for example, are generally made for the purpose of preventing the breakage of an device which a parasitic transistor being turned on causes at the turn-off timing, and of enhancing the avalanche withstand. However, such designs significantly raise the on-resistance of the device, and therefore, the performance of the device is decreased as a result.

As a semiconductor device related to the content of the present application, there is a MOSFET described in the following Patent Document 1, for example. In order to enhance the avalanche withstand in the MOSEFT, for example, decreasing the impurity concentration in an n-type source layer and increasing the impurity concentration in a p-type base layer can be applied, but the point to be improved as described above remains.

[Patent Document] Japanese Patent Laid-open Application No. 2004-158813

### SUMMARY

A semiconductor device according to an aspect of the present invention includes a base region having a first conductive type and including a channel formation region, a drain region having a second conductive type and formed to be adjacent to the base region, a drain electrode formed on a part of the drain region, a source region having the second conductive type and formed to be adjacent to the base region and be spaced from and opposed to the drain region, a gate insulation film formed on the channel formation region, another part of the drain region and a part of the source region, a gate electrode formed on the channel formation region, the other part of the drain region and the part of the source region via the gate insulation film to be opposed to them, a short electrode formed to include a top of another part of the source region, with a contact length being 0.4 μm to 0.8 μm in a part of maximum length with the source region in a direction in which the source region is opposed to the drain region, a region having the first conductive type and a higher impurity concentration than the base region, which is provided at an opposite side of the source region from a side opposed to the drain region and at an underside of the short electrode to be adjacent to the base region, a semiconductor substrate having the first conductive type and located at an underside of the region, and a source electrode formed at an underside of the semiconductor substrate.

Further, a semiconductor device according to another aspect of the present invention includes a base region having a first conductive type and including a channel formation region, a drain region having a second conductive type and formed to be adjacent to the base region, a drain electrode formed on a part of the drain region, a source region having the second conductive type and formed to be adjacent to the base region, to be spaced from and opposed to the drain region, and to be provided at intervals in a direction orthogonal to a direction opposed to the drain region, a gate insulation film formed on the channel formation region, another part of the drain region and a part of each portion of the source region, a gate electrode formed on the channel formation region, the other part of the drain region and the part of each portion of the source region via the gate insulation film to be opposed to them, a short electrode formed to include a top of another part of each portion of the source region, a region having the first conductive type and a higher impurity concentration than the base region, which is provided at an opposite side of each portion of the source region from a side opposed to the drain region and at an underside of the short electrode to be adjacent to the base region, a semiconductor substrate having the first conductive type and located at an underside of the region, and a source electrode formed at an underside of the semiconductor substrate.

### BRIEF DESCRIPTION OF THE DRAWINGS

FIG. 1 is a structural diagram schematically showing a virtual top surface of a semiconductor device (MOSFET) according to one embodiment of the present invention.

FIG. 2 is a structural diagram schematically showing a sectional structure in the arrow direction in an equivalent of a position A to Aa of the MOSFET shown in FIG. 1.

FIG. 3 is a structural diagram schematically showing a sectional structure in the arrow direction in an equivalent of a position B to Ba of the MOSFET shown in FIG. 1.

FIG. 4 is a graph showing a result of obtaining an electric current density in each position in a source region by simulation.

FIG. 5 is a structural diagram schematically showing a virtual top surface of a semiconductor device (MOSFET) according to another embodiment of the present invention.

FIG. 6 is a structural diagram schematically showing a sectional structure in the arrow direction in an equivalent of a position C to Ca of the MOSFET shown in FIG. 5.

FIG. 7 is a structural diagram schematically showing a virtual top surface of a semiconductor device (MOSFET) according to still another embodiment of the present invention.

FIG. 8 is a structural diagram schematically showing a sectional structure in the arrow direction in an equivalent of a position D to Da of the MOSFET shown in FIG. 7.

FIG. 9 is a structural diagram schematically showing a virtual top surface of a semiconductor device (MOSFET) according to yet another embodiment of the present invention.

FIG. 10 is a structural diagram schematically showing a sectional structure in the arrow direction in an equivalent of a position E to Ea of the MOSFET shown in FIG. 9.

### DETAILED DESCRIPTION

### Description of the Embodiments

Though embodiments of the present invention are described with reference to the drawings, but these drawings are presented only for an illustrative purpose, and in no way limit the invention.

According to a semiconductor device relating to one mode of the present invention, a contact length of the short electrode (=an intermediate electrode which is electrically continuous with the source electrode) and the source region (length in a direction opposed to the drain region) is shortened to minimum limit in a range securing a necessary length, and is the length of 0.4 μm to 0.8 μm. With such a short length, the potential of the source region has less difference as compared with a potential of a base region via the short electrode and the region (high impurity concentration region). This is because the high impurity concentration region has a resistance as compared with metals though it has a high impurity concentration, and voltage drop occurs via the high impurity concentration region.

By suppressing the voltage drop to be low, it becomes possible to conduct an avalanche current which occurs at a turn-off timing to the high impurity concentration region effectively. Namely, passage of the avalanche current directly to the source region from the base region (or from the source region to the base region) due to a voltage change in the base region (namely, a parasitic transistor constituted of a drain, a base and a source being turned on by this) is prevented. Therefore, the avalanche withstand can be increased without requiring the decease in impurity concentration of a source layer and the increase in impurity concentration of a base layer.

The reason why the above described contact length is set at 0.4 μm to 0.8 mμ is that an electric current from the source region to the short electrode (or from the short electrode to the source region) is found out to flow sufficiently if the contact length of 0.4 μm is secured as their contact length as a result of simulation. In reality, it is difficult to set the contact length exactly at 0.4 μm from the viewpoint of a mask positioning accuracy and the like in a manufacturing process. Considering that a total machining accuracy is about ±0.2 μm with a mask positioning accuracy under an existing state being about ±0.1 μm and with a etching accuracy of an interlayer film or the like by a mask being about ±0.1 μm, 0.6 μm is adopted as the design center and by taking the machining accuracy into consideration, 0.4 μm to 0.8 μm is set as the condition.

As a form of the semiconductor device, the first conductive type may be set as a p-type and the second conductive type may be set as an n-type. In this case, an n-channel MOSFET is constructed, which is suitable for the case where an electric current is passed to a source electrode from a drain electrode. On the other hand, the first conductive type may be set at an n-type, and the second conductive type may be set at a p-type. In this case, a p-channel MOSFET is constructed, which is suitable for the case where an electric current is passed to the drain electrode from the source electrode.

As a form, the drain region may have a region with a comparatively high impurity concentration and a region with a comparatively low impurity concentration, and a part of the region with the comparatively low impurity concentration may be opposed to the gate electrode via the gate insulation film, while the region with the comparatively high impurity concentration may not be opposed to the gate electrode. This is the structure which relieves an electric field concentration at the end portion of the gate electrode and improves the withstand voltage.

Here, an impurity concentration of the source region may be higher than an impurity concentration of the region with the comparatively low impurity concentration of the drain region. This is the conclusion of the fact that it is not especially necessary to lower the impurity concentration of the source region.

Besides, as a form, the source region may have a comb-shaped plane shape at an opposite side from the side opposed to the drain region. According to such a shape of the source region, a difference in potential between the source region and the base region via a short electrode and the first conductive type region (high-impurity concentration region) in the recessed portion of the comb shape can be made smaller. Namely, the avalanche withstand can be further increased.

Here, the above described comb shape of the source region may be made to have a shape having recessed portions of the comb each having width twice to four times as large as width of each projected portion of the comb. This is an index for effectively passing the avalanche current to (from) the first conductive type region.

Besides, as a form, the source region may have a comb-shaped plane shape at a side opposed to the drain region, and may have a part opposed to the gate electrode via the gate insulation film only at projected portions of the comb. The difference in potential between the source region and the base region via the short electrode and the first conductive type region (high impurity concentration region) can be also made smaller in the recessed portions of the comb shape by such a shape of the source region. Namely, the avalanche withstand can be further increased.

As a form, the semiconductor substrate may be a silicon substrate having the first conductive type. This is one example, and other than this, this may be each of the substrates having the first conductive type of GaAs, SiC, GaN, SiGe, C and the like.

Besides, as a form, a plurality of groups each constituted of the drain region, the source region and the first conductive region may be formed. Thereby, the gate electrode wiring resistance to each group is leveled and a variation in the transistor operation can be suppressed.

Here, a layout of the drain region and the source region in each of the plurality of groups formed may be reverse in groups adjacent in a direction in which the drain region and the source region are opposed to each other. According to this, the drain region can be shared by the adjacent groups, the first conductive type region adjacent to the source region can be shared by the adjacent groups, and the efficiency for the layout of the plurality of groups can be enhanced. Thereby, the channel density is enhanced and the on-resistance can be made low.

Besides, as a form of the semiconductor device, an on-resistance may be 20 mΩ or less. This is the concrete value of the on-resistance which is sufficiently low in practical use.

Besides, according to a semiconductor device relating to another mode of the present invention, a source region is provided at intervals in a direction orthogonal to a direction opposed to a drain region. A first conductive type region having a higher impurity concentration than a base region is provided at an opposite side of the source region from a side opposed to the drain region and at a position adjacent to the base region. According to such a structure, a parasitic transistor is not formed at a part without the source region, and it becomes possible to efficiently conduct the avalanche current which occurs at the turn-off timing to the area with the high impurity concentration in a part where the parasitic transistor is not formed. Namely, in a part including a part where the source region exists the avalanche current is efficiently prevented from flowing to the source region from the base region (or from the source region to the base region) (namely, the parasitic transistor constituted of the drain, the base and the source is prevented from being turned on by this). Thereby, the avalanche withstand can be increased without especially requiring the decrease in impurity concentration of the source layer and the increase in impurity concentration of the base layer.

As a form of the semiconductor device, the first conductive type may be also a p-type, and the second conductive type may be also an n-type.

Besides, as a form, the drain region may have an area with a comparatively high impurity concentration and an area with a comparatively low impurity concentration, and a part of the area with the comparatively low impurity concentration may be opposed to the gate electrode via the gate insulation film, while the area with the comparatively high impurity concentration may not be opposed to the gate electrode. This is the structure which relieves an electric field concentration at the end portion of the gate electrode and improves the withstand voltage.

Here, an impurity concentration of each portion of the source region may be higher than an impurity concentration of the region with the comparatively low impurity concentration of the drain region. This is the conclusion of the fact that it is not necessary to especially lower the impurity concentration of the source region.

Besides, as a form, the disposition of the respective portions of the source region at intervals may be 30% to 50% as a duty ratio. This is an index for passing the avalanche current to (from) the first conductive type region more effectively while suppressing the on-resistance.

Besides, as a form, the semiconductor substrate may be a silicon substrate having the first conductive type. This is one example, and other than this, this may be each of the substrates having the first conductive type of GaAs, SiC, GaN, SiGe, C and the like.

Besides, as a form, a plurality of groups each constituted of the drain region, each portion of the source region and the first conductive type region may be formed. Thereby, the gate electrode wiring resistance to each group is leveled and a variation in the transistor operation can be suppressed.

Here, a layout of the drain region and the source region each in each of the plurality of groups formed may be reverse in groups adjacent in a direction in which the drain region and the source region each are opposed to each other. According to this, the drain region can be shared by the adjacent groups, the first conductive type region adjacent to the source region can be shared by the adjacent groups, and the efficiency for the layout of a plurality of groups can be enhanced. Thereby, the channel density can be enhanced and the on-resistance can be made low.

Besides, as a form of the semiconductor device, an on-resistance may be 20 mΩ or less. This is the concrete value of the on-resistance sufficiently small in practical use.

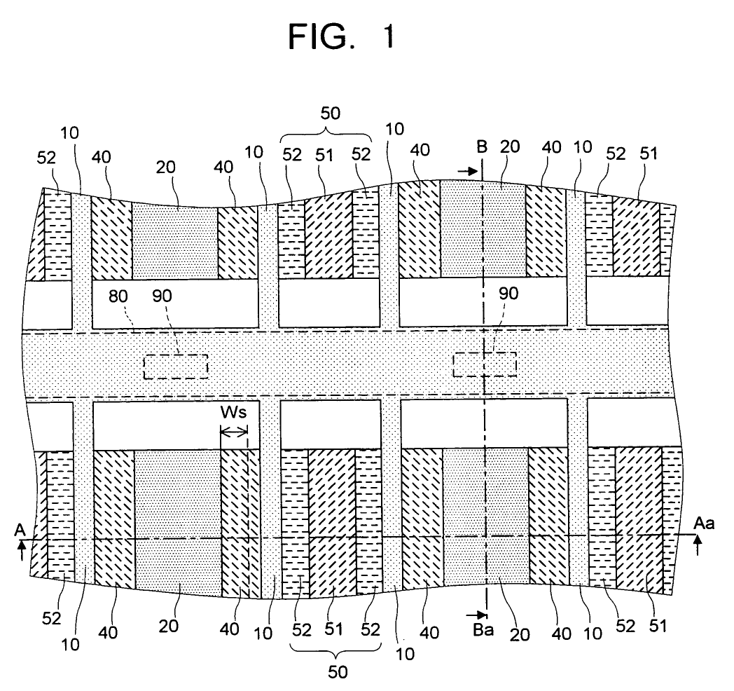

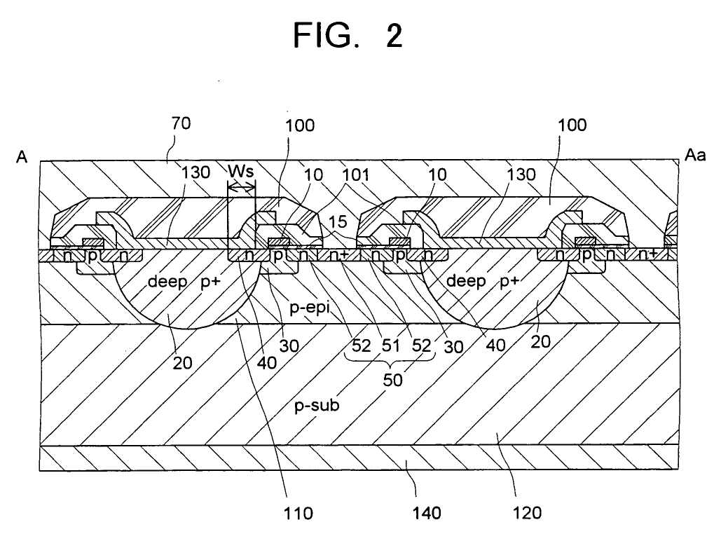

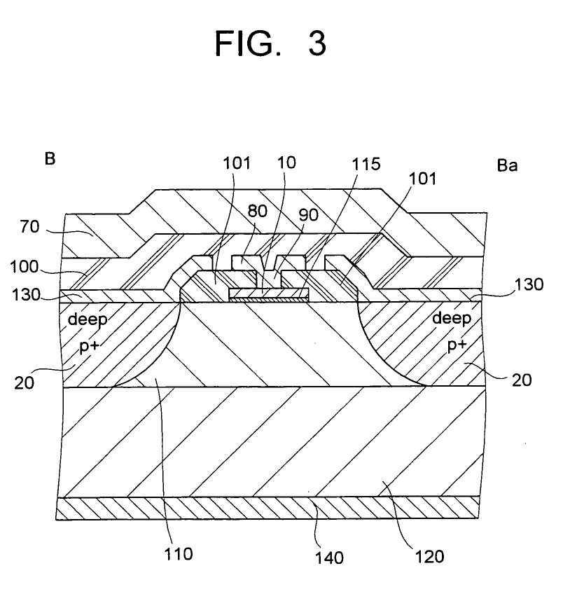

Based on the above, an embodiment of the present invention will be described with reference to the drawings hereinafter. FIG. 1 is a structural diagram schematically showing a virtual top surface of a semiconductor device (MOSFET) according to one embodiment of the present invention. FIG. 2 is a structural diagram schematically showing a sectional structure in the arrow direction in an equivalent of a position A to Aa of the MOSFET shown in FIG. 1. FIG. 3 is a structural diagram schematically showing a sectional structure in the arrow direction in an equivalent of a position B to Ba of the MOSFET shown in FIG. 1. In these drawings, the same parts are given the same reference numerals.

As shown in FIGS. 1 to 3, the MOSFET has gate electrodes 10, gate insulation films 15, deep p-type regions 20 (first conductive type regions), p-type base regions 30, n-type source regions 40, n-type drain regions 50, a drain electrode 70, gate electrode wiring 80, gate electrode contacts 90, interlayer insulation films 100, interlayer insulation films 101, a p-type epitaxial layer 110, a p-type semiconductor substrate 120, short electrodes 130 and a source electrode 140. The n-type drain region 50 is constituted of an LDD region 52 and an n-type drain region 51 excluding this.

FIG. 1 is the diagram of “a virtual top surface” for the purpose of showing the top surface of the semiconductor regions in FIGS. 2 and 3 (regions such as the deep p-type region 20, the p-type base region 30, the n-type source region 40, the n-type drain region 50 and the like) for convenience of explanation. However, only the gate electrodes 10 provided on the top side of the semiconductor regions are also shown in FIG. 1.

Structurally, a channel can be formed at a part of the p-type base region 30 opposed to the gate electrode 10 via the gate insulation film 15. When the channel is formed, an electric current flows through a path of the drain electrode 70, the adjacent n-type drain region 50, the adjacent channel of the p-type base region 30, the adjacent n-type source region 40, the adjacent short electrode 130, the adjacent deep p-type region 20, the adjacent p-type semiconductor substrate 120 and the adjacent source electrode 140 (flow of electron is in the reverse order). For the purpose of forming the channel in the p-type base region 30, the gate electrode 10 has planar overlaps with each part of the n-type drain region 50 (the LDD region 52) and the n-type source region 40 via the gate insulation film 15.

The p-type base region 30 is also in contact with the deep p-type region 20, and thereby, electric potential of the p-type base region 30 is kept at the electric potential at the n-type source region 40 side. The impurity concentration of the deep p-type region 20 is higher than that of the p-type base region 30, and therefore, the deep p-type region 20 has a higher electric conductivity. The n-type source region 40 has a further high impurity concentration and a further high electric conductivity than those of the deep p-type region 20, but has a lower electric conductivity than that of the short electrode 130 (because the short electrode 130 is metal).

As an entire structure, a plurality of groups each constituted of the n-type drain region 50, the n-type source region 40 and the deep p-type region 20 are formed (in the longitudinal direction, and in the latitudinal direction in FIG. 1). Thereby, the gate electrode wiring resistance to each group is leveled and a variation in the transistor operation can be suppressed. The layout of the n-type drain region 50 and the n-type source region 40 in each of the plurality of groups formed are reverse in the groups adjacent in a direction in which the n-type drain region 50 and the n-type source region 40 are opposed to each other. According to this, the n-type drain region 50 and the deep p-type region 20 are shared by the adjacent groups as shown in the drawings, and the efficiency for the layout of a plurality of groups can be enhanced. Thereby, the channel density can be enhanced and the on-resistance can be made low.

The manufacturing process steps in the semiconductor region can be the sequence of, for example, 1) formation of the p-type epitaxial layer 110 on the p-type semiconductor substrate 120, 2) formation of the deep p-type region 20 in the p-type epitaxial layer 110 to reach the p-type semiconductor substrate 120, 3) formation of the p-type base region 30 to be shallower and wider in plane than the deep p-type region 20, 4) formation of the LDD region 52 to be shallower than the p-type base region 30, and 5) formation of the n-type source region 40 and the n-type drain region 51 to be shallower than the p-type base region 30.

A p-type silicon substrate can be used for the p-type semiconductor substrate 120, for example, boron can be used for the p-type impurity, and for example, phosphor can be used for the n-type impurity. However, in only the above described process step 5), for example, arsenic can be used as the n-type impurity. By the above described process step 5), the impurity concentration of the n-type source region 40 and the n-type drain region 51 is made higher than that of the LDD region 52 with the same conductive type as the LDD region 52. The LDD region 52 is formed to relieve an electric field concentration at the end portion of the gate electrode 10 and improve the withstand voltage.

Meanwhile, the manufacturing process steps of the structure on the upper side from the semiconductor region can be in the sequence of, for example, 1) formation of the gate insulation film 15, 2) formation of the gate electrode 10, 3) formation of the interlayer insulation film 101, 4) formation of the short electrode 130, 5) formation of the interlayer insulation film 100, and 6) formation of the drain electrode 70. Formation of the short electrode 130 can be made at the same time with the formation of the gate electrode wiring 80 (see FIG. 3).

The concrete dimension of each part is as follows, for example. The depth of the p-type epitaxial layer 110 from the semiconductor region top surface is 2 μm, the depth of the p-type base region 30 is 0.5 μm to 1.0 μm, the depth of the n-type drain region 50 and the n-type source region 40 is 0.1 μm to 0.3 μm, the channel length is 0.5 μm to 1.0 μm, the length of the portion of the n-type source region 40, which is in the direction opposed to the n-type drain region 50 and is not in contact with the short electrode 130, is 0.6 μm, and the like. The length in the latitudinal direction in the drawing of one group constituted of the n-type drain region 50, the n-type source region 40 and the deep p-type region 20 is about 5 μm to 10 μm, and the length thereof in the longitudinal direction in the drawing is about 100 μm.

Contact length Ws of the n-type source region 40 and the short electrode 130 in the direction in which the n-type source region 40 is opposed to the n-type drain region 50 in FIGS. 1 and 2 is an important indicator in the performance (the avalanche withstand) of the MOSFET. When this length is long, a large voltage drop occurs due to the resistance of the deep p-type region 20 in the path in which the potential of the n-type source region 40 is transmitted to the p-type base region 30 via the short electrode 130 and the deep p-type region 20. In such a case, the avalanche current passing through the p-type base region 30 directly flows to the n-type source region 40 in the forward direction of p to n, and the parasitic transistor of npn constructed by the n-type drain region 50, the p-type base region 30 and then-type source region 40 is in the on-state. Therefore, a sufficient avalanche withstand cannot be ensured.

Accordingly, it is suitable that the above described contact length Ws is as short as possible in the viewpoint of avalanche withstand. On the other hand, the short electrode 130 with which the n-type source region 40 is in contact is interposed to ensure the flow of the electric current in the n-type source region 40, the short electrode 130 and the deep p-type region 20, and therefore, the contact length Ws cannot be made so short as to inhibit the flow of the electric current.

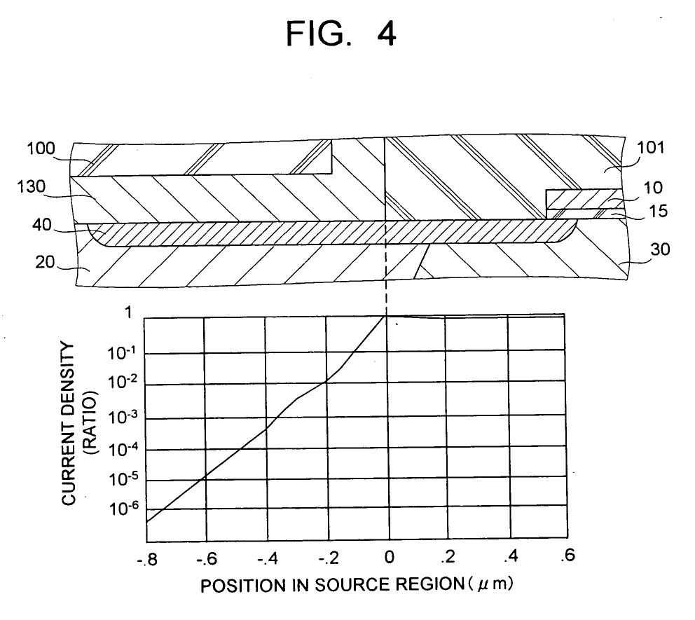

FIG. 4 is a graph showing the result of obtaining the current density in each position in the source region (n-type source region 40) by simulation. The horizontal axis represents the position in the latitudinal direction in the drawing in the n-type source region 40, and the vertical axis represents a ratio of the current density (log indication). As for the position in the n-type source region 40 of the horizontal axis, the position which is in contact with the short electrode 130 being the nearest to the gate electrode 10, is set as an origin (position 0) as shown by contrast with the schematic diagram shown on an upper side of the graph.

As is understood from FIG. 4, the current density in the n-type source region 40 is from the area near the gate electrode 10 to the contact position (position 0) of the short electrode 130, from which the current density starts to drop abruptly to be over 1/100 at the position of −0.2 μm, and about 1/1000 at the position of −0.4 μm. This is the result of the difference in electric resistance between the n-type source region 40 and the short electrode 130. If the area up to the position of 1/1000 is tentatively considered to be the area where an electric current flows, the other area in the n-type source region 40 than this is an unnecessary area.

From the result shown in FIG. 4, it can be a guideline to ensure 0.4 μm as the contact length Ws. Here, in reality, the positioning accuracy of formation of the short electrode 130 with respect to the position of formation of the n-type source region 40 is limited in the manufacturing process. As is understood from the explanation of the above described manufacturing process, these positions are specified by totally different masks. Therefore, it is actually impossible to make the contact length Ws as the design value.

Thus, the positioning accuracy which is obtained under the present circumstances is, for example, ±0.2 μm. Details are about ±0.1 μm as the mask positioning accuracy, and about ±0.1 μm as the etching accuracy of the interlayer film and the like by the mask. Therefore, 0.6 μm is adopted as a design center, and in addition to the design center by taking the positioning accuracy into consideration, the MOSFET can be produced so that the contact length Ws is 0.4 μm to 0.8 μm. Thereby, the MOSFET which makes it mutually compatible to secure an avalanche withstand and to avoid rise of the on-resistance can be obtained. As a concrete example, the MOSFET with the rating withstand voltage of, for example, 30 V and with the on-resistance of, for example, 10 mΩ to 20 mΩ is obtained.

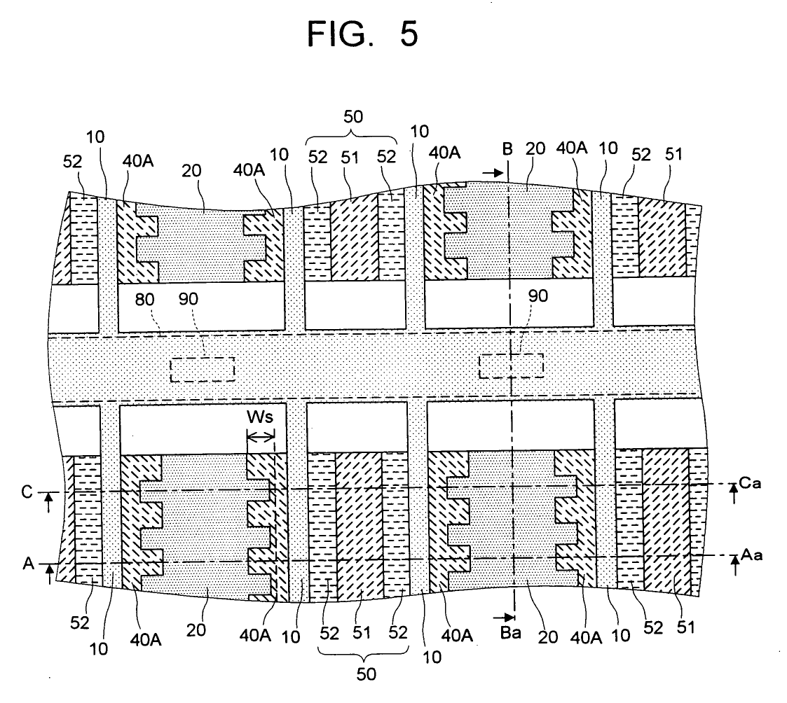

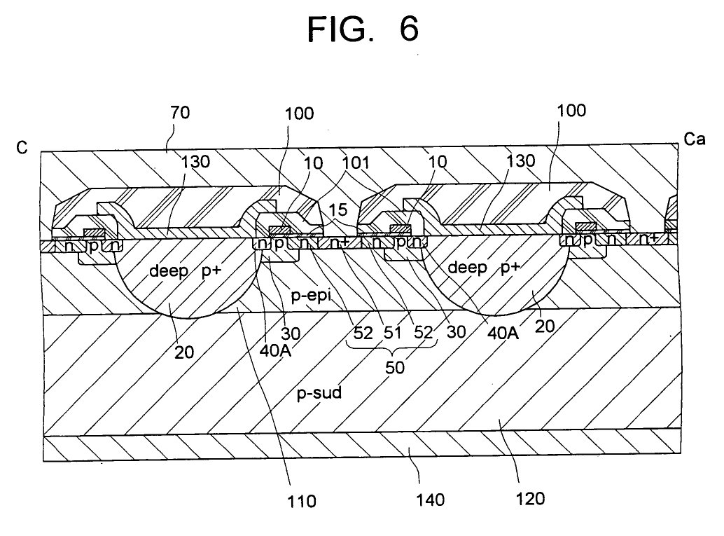

Next, a semiconductor device (MOSFET) according to another embodiment of the present invention will be described with reference to FIGS. 5 and 6. FIG. 5 is a structural diagram schematically showing a virtual top surface of the semiconductor device (MOSFET) according to another embodiment of the present invention, and FIG. 6 is a structural diagram schematically showing a sectional structure in the arrow direction in an equivalent of a position C to Ca of the MOSFET shown in FIG. 5. In FIGS. 5 and 6, the same or equivalent parts as or to the already explained parts are given the same reference numerals. The explanation of such parts is omitted as long as additional explanation is not needed. The sectional structures in the position A to Aa and the position B to Ba in FIG. 5 are the same as those in FIGS. 2 and 3 already explained, and therefore, illustration thereof will be omitted.

In this embodiment, an n-type source region 40A is patterned to have a comb-shaped plane shape in an opposite side from a side opposed to the n-type drain region 50. The length of contact of the n-type source region 40A and the short electrode 130 in the direction in which the n-type source region 40A is opposed to the n-type drain region 50 corresponds to the contact length Ws of the above described explanation in a long part (projected portion of the comb shape).

By patterning the n-type source region 40A into the comb shape like this, the path through which the potential of the n-type source region 40A is transmitted to the p-type base region 30 via the short electrode 130 and the deep p-type region 20 becomes shorter in recessed portions of the comb shape (see FIG. 6). Namely, the possibility of the p-type base region 30 having abnormally different potential from that of the n-type source region 40A becomes smaller, and it is made possible to efficiently conduct the avalanche current occurring at the turn-off timing to the deep p-type region 20. Therefore, occurrence of an on-state of the parasitic transistor can be prevented, and the avalanche withstand can be further ensured.

A cut amount of the recessed portion of the comb shape can be set at, for example, 0.3 μm. According to this, as the contact length of the n-type source region 40A and the short electrode 130 is 0.4 μm to 0.8 μm in the projected portion of the comb (in conformance with the above described embodiment), the contact length of the n-type source region 40A and the short electrode 130 can be made 0.1 μm to 0.5 μm in the recessed portion of the comb shape. Namely, even if the contact length is deviated in the long direction in positioning, the parts suppressed to the contact length of 0.5 μm occur, and it is preferable in the sense of avoiding the reduction in the avalanche withstand.

The width of the recessed portion of the comb can be set to be, for example, twice to four times as large as the width of the projected portion of the comb. While the increase in the avalanche withstand is expected by making the width of the recessed portion comparatively wider like this, an increase in the on-resistance due to the decrease in the contact area with the short electrode 130 as a result of the width of the projected portions being comparatively small is very small as understood from the current density distribution shown in FIG. 4, which is more advantageous in total.

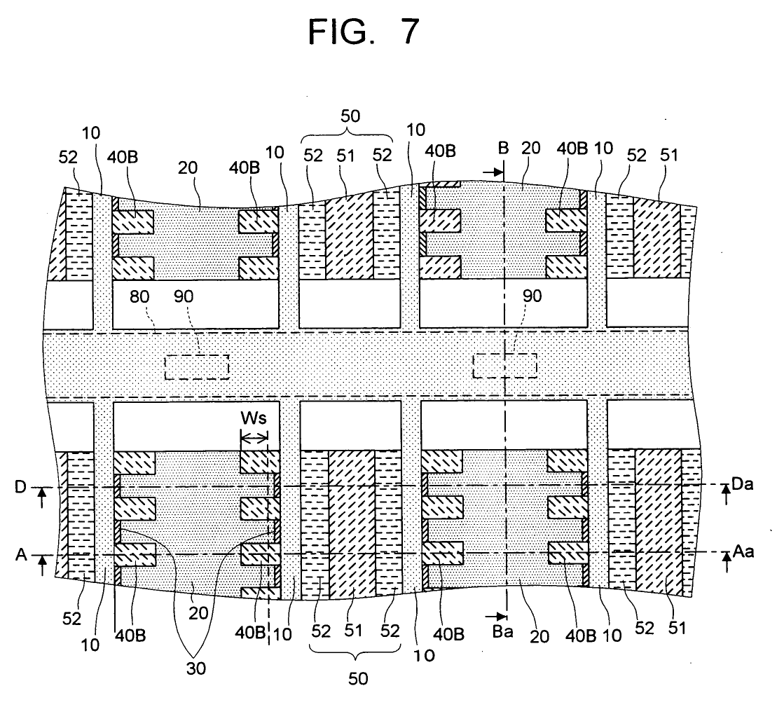

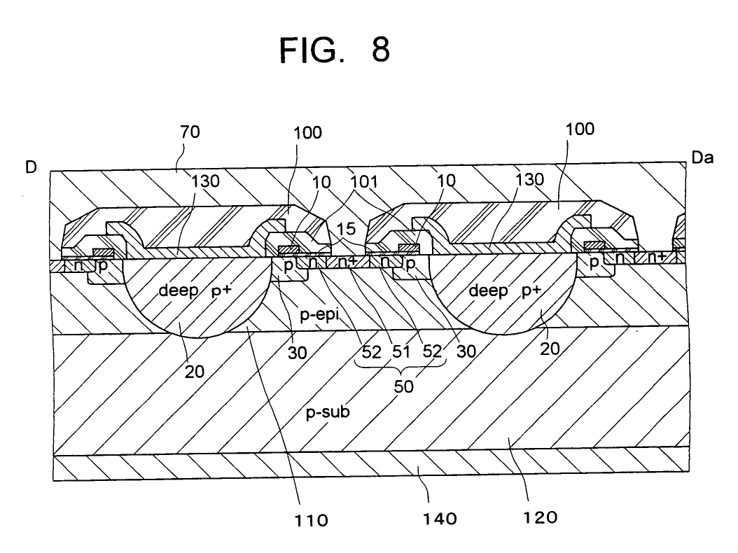

Next, a semiconductor device (MOSFET) according to still another embodiment of the present invention will be described with reference to FIGS. 7 and 8. FIG. 7 is a structural diagram schematically showing a virtual top surface of the semiconductor device (MOSFET) according to still another embodiment of the present invention. FIG. 8 is a structural diagram schematically showing a sectional structure in the arrow direction in an equivalent of a position D to Da of the MOSFET shown in FIG. 7. In FIGS. 7 and 8, the same or equivalent parts as or to the parts already explained are given the same reference numerals. The explanation of these parts will be omitted as long as additional explanation thereof is not needed. The sectional structures in the position A to Aa and the position B to Ba in FIG. 7 are the same as those in FIGS. 2 and 3 which are already explained, and therefore, illustration thereof will be omitted.

In this embodiment, the n-type source regions 40B are provided at intervals in a direction orthogonal to the direction in which the n-type source regions 40B are opposed to the n-type drain region 50. Therefore, a channel is not formed in the p-type base region 30 corresponding to the portions of the intervals where the n-type source regions 40B are not provided (See FIG. 8: in these portions, the parasitic transistor is not formed). Thereby, the channel formation density decreases as compared with the above described respective embodiments, and therefore, the on-resistance increases to some extent. However, the path through which the potential of the n-type source region 40B is transmitted to the p-type base region 30 via the short electrode 130 and the deep p-type region 20 is ensured at a shorter distance which extends in the lateral direction in the portions of the intervals where the n-type source regions 40B are not provided, and an increase in the avalanche withstand is realized.

The contact length Ws of each of the n-type source regions 40B and the short electrode 130 in the direction in which the n-type source regions 40B are opposed to the n-type drain region 50 corresponds to the contact length Ws in each of the above described embodiments, but in this embodiment, the limitation of 0.8 μm at the maximum does not need to be especially provided as in the above described embodiments. As explained above, this is because the path through which the potential of the n-type source regions 40B is transmitted to the p-type base region 30 via the short electrode 130 and the deep p-type region 20 is ensured to extend in the lateral direction in the portions of the intervals where the n-type source regions 40B are not provided.

The disposition of the n-type source regions 40B at intervals can be set at, for example, 30% to 50% as the duty ratio. When the duty ratio is taken to be high, an increase in the on-resistance can be kept to be small without sacrificing the channel formation density too much. When the duty ratio is set to be too high, the intervals where the n-type source regions 40B are not provided become too narrow, and therefore, limitation in machining accuracy occurs.

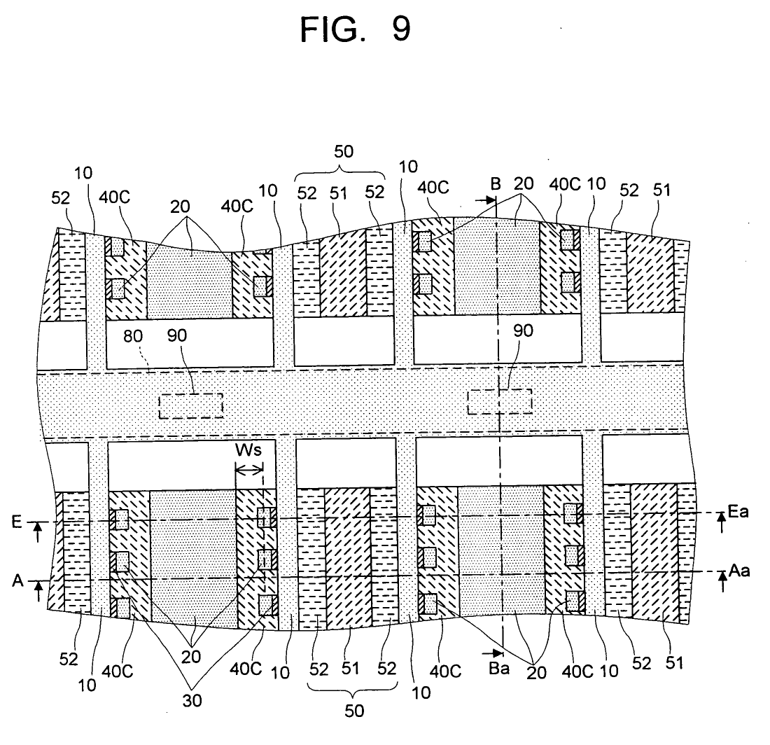

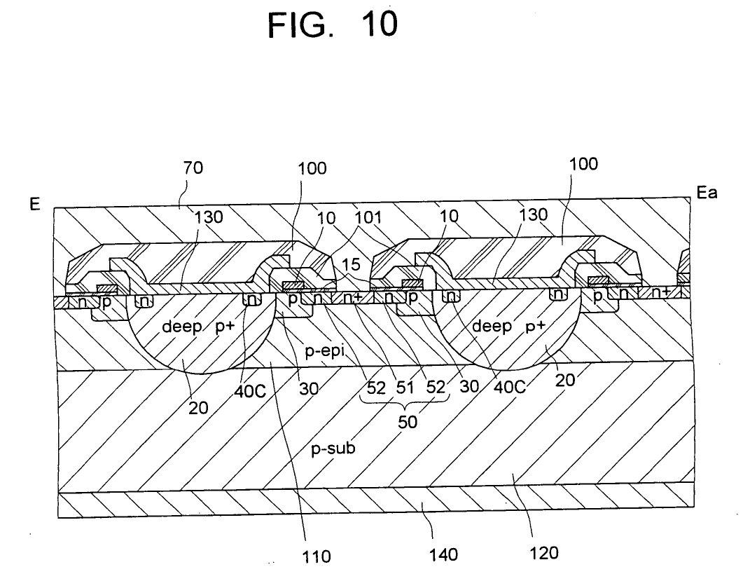

Next, a semiconductor device (MOSFET) according to yet another embodiment of the present invention will be described with reference to FIGS. 9 and 10. FIG. 9 is a structural diagram schematically showing a virtual top surface of the semiconductor device (MOSFET) according to yet another embodiment of the present invention. FIG. 10 is a structural diagram schematically showing a sectional structure in the arrow direction in an equivalent of a position E to Ea of the MOSFET shown in FIG. 9. In FIGS. 9 and 10, the same or equivalent parts as or to the parts already explained are given the same reference numerals. The explanation of these parts will be omitted as long as additional explanation thereof is not needed. The sectional structures in the position A to Aa and the position B to Ba in FIG. 9 are the same as those in FIGS. 2 and 3 which are already explained, and therefore, illustration thereof will be omitted.

This embodiment is the same as the embodiment shown in FIGS. 7 and 8 in concept, and is the mode in which n-type source region 40C has a comb-shaped plane shape at the side opposed to the n-type drain region 50, and has a part opposed to the gate electrode 10 via the gate insulation film 15 only at the projected portions of the comb (namely, only at the projected portions of the comb channels are formed). Namely, the recessed portions of the comb shape have the same function as the interval portions without the n-type source regions 40B of the embodiment shown in FIGS. 7 and 8. Therefore, avalanche withstand can be enhanced.

The maximum contact length Ws of the n-type source region 40C and the short electrode 130 in the direction in which the n-type source region 40C is opposed to the n-type drain region 50 corresponds to the contact length Ws in each of the above described embodiments, but in this embodiment, as well as in the embodiment shown in FIGS. 7 and 8 it is not especially necessary to provide such a limitation as the maximum contact length Ws of 0.8 μm. However, it does not matter to produce the semiconductor device to have the maximum contact length Ws of 0.8 μm. The relationship between the width of the projected portion and the recessed portion of the comb shape of the n-type source region 40C can be considered to be similar to the duty ratio of the disposition of the n-type source region 40B in the embodiment shown in FIGS. 7 and 8.

It is to be understood that the present invention is not intended to be limited to the specific embodiments illustrated and described here, but all changes which come within the meaning and range of equivalency of the following claims are intended to be embraced therein.

What is claimed is:

1. A semiconductor device, comprising:
a base region having a first conductive type and including a channel formation region;
a drain region having a second conductive type and formed to be adjacent to the base region;
a drain electrode formed on a part of the drain region;
a source region having the second conductive type and formed to be adjacent to the base region and be spaced from and opposed to the drain region;
a gate insulation film formed on the channel formation region, another part of the drain region, and a part of the source region;
a gate electrode formed on the channel formation region, the other part of the drain region, and the part of the source region via the gate insulation film to be opposed to the channel formation region, the other part of the drain region, and the part of the source region;
a short electrode formed to include a top of another part of the source region, with a contact length being 0.4 μm to 0.8 μm in a part of maximum length with the source region in a direction in which the source region is opposed to the drain region;
a fourth region having the first conductive type and an a higher impurity concentration than that of the base region, which is provided at an opposite side of the source region from a side opposed to the drain region and at an underside of the short electrode to be adjacent to the base region;
a semiconductor substrate having the first conductive type and located at an underside of the fourth region; and
a source electrode formed at an underside of the semiconductor substrate.

2. A semiconductor device as set forth in claim 1, wherein the first conductive type is a p-type, and the second conductive type is an n-type.

3. A semiconductor device as set forth in claim 1, wherein the drain region has a region with a comparatively high impurity concentration and a region with a comparatively low impurity concentration, and a part of the region with the comparatively low impurity concentration is opposed to the gate electrode via the gate insulation film, while the region with the comparatively high impurity concentration is not opposed to the gate electrode.

4. A semiconductor device as set forth in claim 3, wherein an impurity concentration of the source region is higher than an impurity concentration of the region with the comparatively low impurity concentration of the drain region.

5. A semiconductor device as set forth in claim 1, wherein the source region has a comb-shaped plane shape at an opposite side from a side opposed to the drain region.

6. A semiconductor device as set forth in claim 5, wherein the comb-shaped plane shape of the source region is a shape having a recessed portion of a comb with a width of twice to four times as large as a width of a projected portion of the comb.

7. A semiconductor device as set forth in claim 1, wherein the source region has a comb-shaped plane shape in a side opposed to the drain region, and has a part opposed to the gate electrode via the gate insulation film in only a projected portion of a comb.

8. A semiconductor device as set forth in claim 1, wherein the semiconductor substrate is a silicon substrate having the first conductive type.

9. A semiconductor device as set forth in claim 1, wherein a plurality of groups each constituted of the drain region, the source region, and the fourth region are formed.

10. A semiconductor device as set forth in claim 9, wherein a layout of the drain region and the source region in each of the plurality of groups formed is reverse in groups adjacent in a direction in which the drain region and the source region are opposed to each other.

11. A semiconductor device as set forth in claim 1, wherein an on-resistance is 20 mΩ or less.

12. A semiconductor device, comprising:
a base region having a first conductive type and including a channel formation region;
a drain region having a second conductive type and formed to be adjacent to the base region;
a drain electrode formed on a part of the drain region;
a source region having the second conductive type and formed to be adjacent to the base region, to be spaced from and opposed to the drain region, and to be provided at intervals in a direction orthogonal to a direction opposed to the drain region;
a gate insulation film formed on the channel formation region, another part of the drain region, and a part of each portion of the source region;
a gate electrode formed on the channel formation region, the other part of the drain region, and the part of each portion of the source region via the gate insulation film to be opposed to the channel formation region, the other part of the drain region, and the part of each portion of the source region;
a short electrode formed to include a top of another part of each portion of the source region;
a fourth region having the first conductive type and a higher impurity concentration than that of the base region, which is provided at an opposite side of each portion of the source region from a side opposed to the drain region and at an underside of the short electrode to be adjacent to the base region;
a semiconductor substrate having the first conductive type and located at an underside of the fourth region; and
a source electrode formed at an underside of the semiconductor substrate.

13. A semiconductor device as set forth in claim 12, wherein the first conductive type is a p-type, and the second conductive type is an n-type.

14. A semiconductor device as set forth in claim 12, wherein the drain region has a region with a comparatively high impurity concentration and a region with a comparatively low impurity concentration, and a part of the region with the comparatively low impurity concentration is opposed to the gate electrode via the gate insulation film, while the region with the comparatively high impurity concentration is not opposed to the gate electrode.

15. A semiconductor device as set forth in claim 14, wherein an impurity concentration of each portion of the source region is higher than an impurity concentration of the region with the comparatively low impurity concentration of the drain region.

16. A semiconductor device as set forth in claim 12, wherein a disposition of respective portions of the source region at intervals is 30% to 50% as a duty ratio.

17. A semiconductor device as set forth in claim 12, wherein the semiconductor substrate is a silicon substrate having the first conductive type.

18. A semiconductor device as set forth in claim 12, wherein a plurality of groups each constituted of the drain region, each portion of the source region, and the fourth region are formed.

19. A semiconductor device as set forth in claim 18, wherein a layout of the drain region and the source region each in each of the plurality of groups formed is reverse in groups adjacent in a direction in which the drain region and the source region each are opposed to each other.

20. A semiconductor device as set forth in claim 12, wherein an on-resistance is 20 mΩ or less.
